(19) United States
(12) Patent Application Publication
(10) Pub. No.: US 2023/0249360 A1
(43) Pub. Date: Aug. 10, 2023

(54) ROBOTIC END EFFECTOR EQUIPPED WITH REPLACEABLE WAFER CONTACT PADS

(71) Applicant: Fabworx Solutions, Inc., Austin, TX (US)

(72) Inventors: MICHAEL DAILEY, Austin, TX (US); THOMAS WALTON, Austin, TX (US); DANIEL ALANIZ, Austin, TX (US)

(21) Appl. No.: 18/010,411

(22) PCT Filed: Jun. 14, 2021
(86) PCT No.: PCT/US21/37300

§ 371 Date: Dec. 14, 2022

Related U.S. Application Data
(60) Provisional application No. 63/038,875, filed on Jun. 14, 2020.

(51) Int. Cl. B25J 15/00; B25J 11/00

(52) U.S. Cl. CPC B25J 15/0019; B25J 11/0095; B25J 15/0095

(57) ABSTRACT

A robotic end effector is provided which includes an end effector blade, and a plurality of wafer support pads disposed on the surface of the end effector blade. Each of the plurality of wafer support pads includes a pad body having a central protrusion and having first and second fasteners disposed on opposing sides of the central protrusion.

### CROSS-REFERENCE TO RELATED APPLICATION

The present application is a national stage filing of PCT/US21/37300, filed on Jun. 14, 2021, which has the same title and the same inventors, and which is incorporated herein by reference in its entirety; which claims priority to U.S. Provisional Application No. 63/038,875 filed Jun. 14, 2020, which has the same title and the same inventors, and which is incorporated herein by reference in its entirety.

### FIELD OF THE DISCLOSURE

The present application relates generally to robotic end effectors, and more particularly to robotic end effectors equipped with replaceable wafer contact pads.

### BACKGROUND OF THE DISCLOSURE

In a typical semiconductor manufacturing process, a single wafer may be exposed to a number of sequential processing steps including, but not limited to, chemical vapor deposition (CVD), physical vapor deposition (PVD), etching, planarization, and ion implantation. These processing steps are typically performed by robots, due in part to the ability of robots to perform repetitive tasks quickly and accurately and to work in environments that are dangerous to humans.

Many modern semiconductor processing systems are centered around robotic cluster tools that integrate a number of process chambers. This arrangement allows multiple sequential processing steps to be performed on the wafer within a highly controlled processing environment, and thus minimizes exposure of the wafer to external contaminants. The combination of chambers in a cluster tool, as well as the operating conditions and parameters under which those chambers are utilized, may be selected to fabricate specific structures using a specific process recipe and process flow. Some commonly used process chambers include degas chambers, substrate pre-conditioning chambers, cool down chambers, transfer chambers, chemical vapor deposition chambers, physical vapor deposition chambers and etch chambers.

Robotic end effectors are a crucial component of cluster tools. These devices are tasked with the actual handling and placement of semiconductor wafers within the tool. Ideally, robotic end effectors operate in a repeatable, high speed manner to provide high tool throughput and high product yields.

The use of ceramic materials in end effectors has become common in the art. Such materials offer superior electrical, thermal and mechanical properties (including high chemical inertness), making them ideal for applications involving significant thermal loads or exposure to chemically harsh environments (such as, for example, etching baths).

Various examples of ceramic end effectors are known to the art. For example, U.S. Pat. No. 7,717,481 (Ng) discloses ceramic robotic end effectors which include a body fabricated from a single mass of ceramic, and having opposing mounting and distal ends. A plurality of contact pads extend upward from the upper surface of the body for supporting the substrate thereon. Notably, the contact pads are integral with the end effector (that is, the contact pads and end effector are formed from a single mass of ceramic).

### BRIEF DESCRIPTION OF THE DRAWINGS

FIGS. 1-3 are illustrations of a first embodiment of a robotic end effector in accordance with the teachings herein.

FIGS. 4-9 are illustrations of a second embodiment of a robotic end effector in accordance with the teachings herein.

FIGS. 10-14 are illustrations of a third embodiment of a robotic end effector in accordance with the teachings herein.

FIGS. 15-18 are illustrations of a fourth embodiment of a robotic end effector in accordance with the teachings herein.

FIGS. 19-30 are illustrations of a fifth embodiment of a robotic end effector in accordance with the teachings herein.

FIG. 31 is an illustration (partially exploded) of a fin assembly in accordance with the teachings herein.

FIG. 32 is an illustration (partially exploded) of a sixth embodiment of a robotic end effector in accordance with the teachings herein.

### SUMMARY OF THE DISCLOSURE

In one aspect, a robotic end effector is provided which comprises an end effector blade; and a plurality of wafer support pads disposed on the surface of said blade; wherein each of said plurality of wafer support pads includes a pad body having a central protrusion and having first and second fasteners disposed on opposing sides of said central protrusion.

In another aspect, a robotic end effector is provided which comprises an end effector blade having a plurality of apertures therein; and a plurality of wafer support pads disposed on the surface of said blade; wherein each of said plurality of wafer support pads includes a rounded head disposed on a shaft, and wherein said shaft rotatingly engages one of said plurality of apertures.

In a further aspect, a robotic end effector is provided which comprises an end effector blade; and a plurality of wafer support pads disposed on said end effector blade; wherein each of said plurality of wafer support pads includes (a) a base plate, (b) a protrusion mount receptacle disposed on said base plate, (c) a protrusion mount which releasably engages said protrusion mount receptacle, and (d) a protrusion mounted on said protrusion mount such that said protrusion extends above the first surface of said blade.

### DETAILED DESCRIPTION

Although the ceramic end effectors disclosed inn U.S. Pat. No. 7,717,481 (Ng) may have some beneficial features, they also have some notable shortcomings. In particular, because the contact pads in the device of Ng are an integral part of the end effector, when these pads become worn over time or otherwise require replacement, it is necessary to replace the entire end effector. Since ceramic end effectors are a costly component of cluster tools, the effective cost of replacing wafer pads is significant. Moreover, replacement of an end effector typically requires recalibration of the associated tool, which requires additional downtime.

Some end effectors have been proposed in the art which feature contact pads that are ostensibly removable. Examples include those disclosed in U.S. 2005/0110292 (Baumann et al.), U.S. 2006/0131903 (Bonora et al.) and U.S. 2016/0218030 (Embertson et al.). However, each of these devices has notable drawbacks.

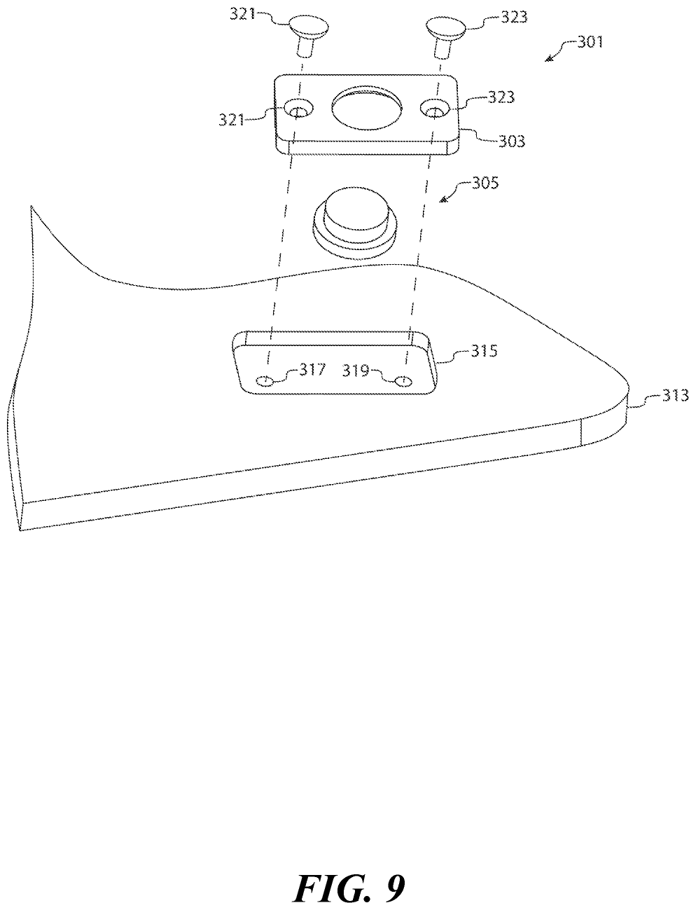

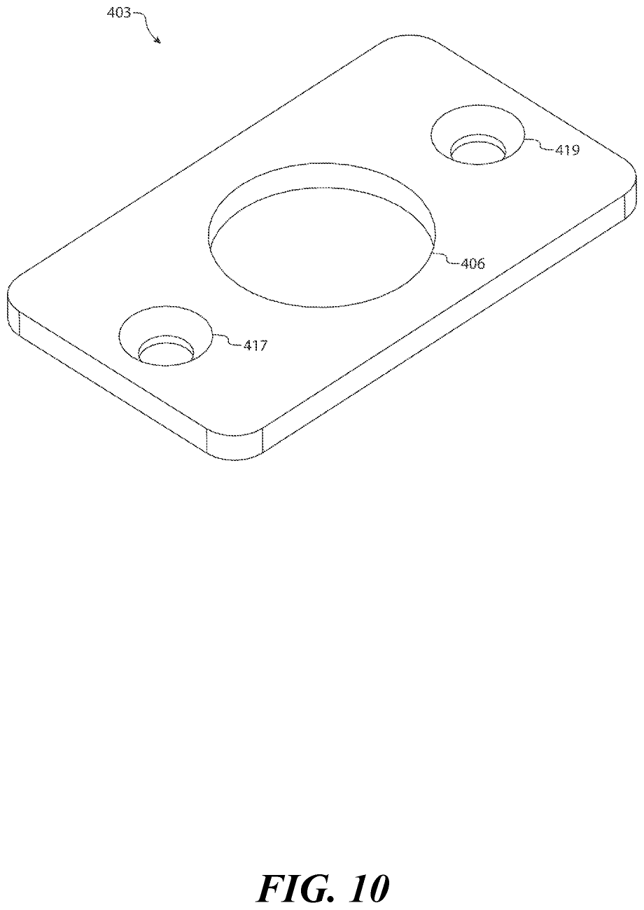

For example, the end effector of Baumann et al. uses a wire spring 50 (see FIGS. 9-10) which rests on a bevel 85 and provides a torsional force to a support pad 77. This force, because of the bevel, purportedly causes the support pad 77 to be forced downward against a non-vacuum support pad cavity bottom 91 and forward into a beveled wall 85. However, the force applied by the wire spring is likely variable from one implementation to another. Moreover, the force applied by the spring would be expected to change as a function of temperature, or due to variations in the dimensions of the pad and the cavity.

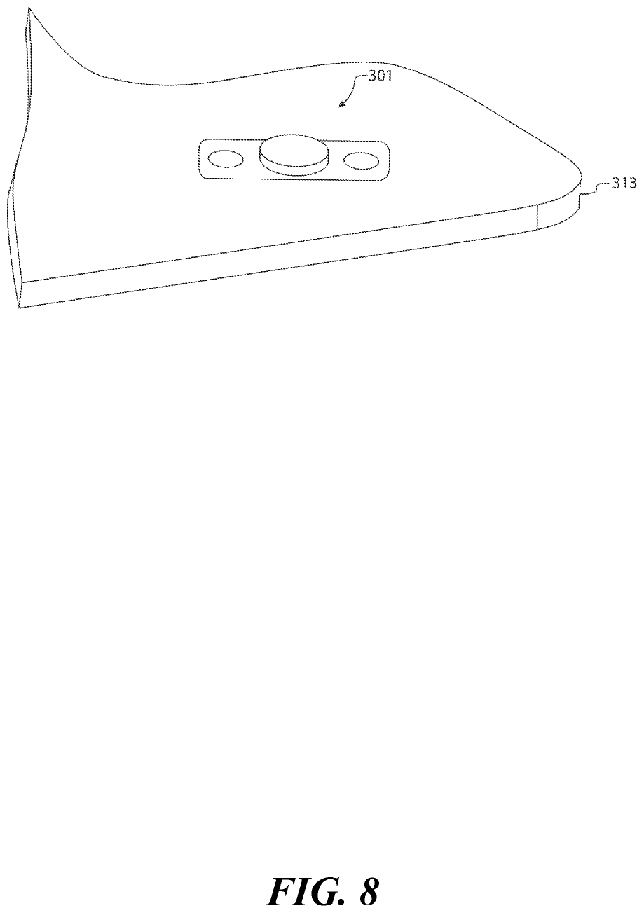

The end effector of Bonora et al. uses wafer support pads 150 (see FIGS. 8A-8C) having a sloped contact surface 152. The protrusions align the bottom support pad 150 on the support plate 102. The protrusions 156 and 158 are inserted into the appropriate mounting holes to align the bottom support pad 150 on the support plate 102. However, the wafer support pads in this end effector engage the entire portion of the edge of the wafer which extends over the pad. Since the generation of particulate contaminates in semiconductor processing is partially a function of the surface area of contact between the wafer and the end effector (or pads thereof), it is desirable to minimize this surface area of contact. Moreover, the contact pads in the end effector of Bonora et al. lack a means to secure them within the cavity, which can lead to their dislodgement during use.

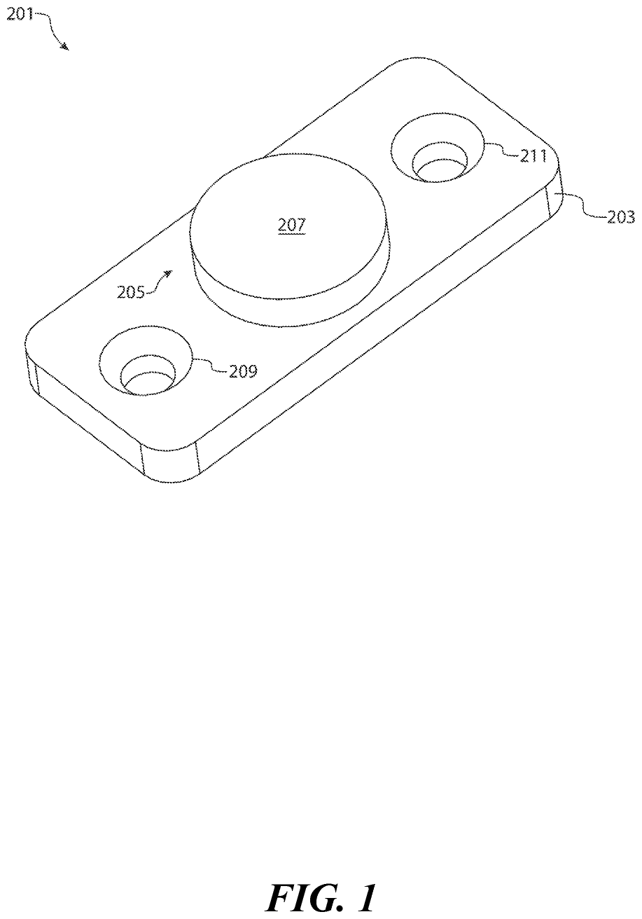

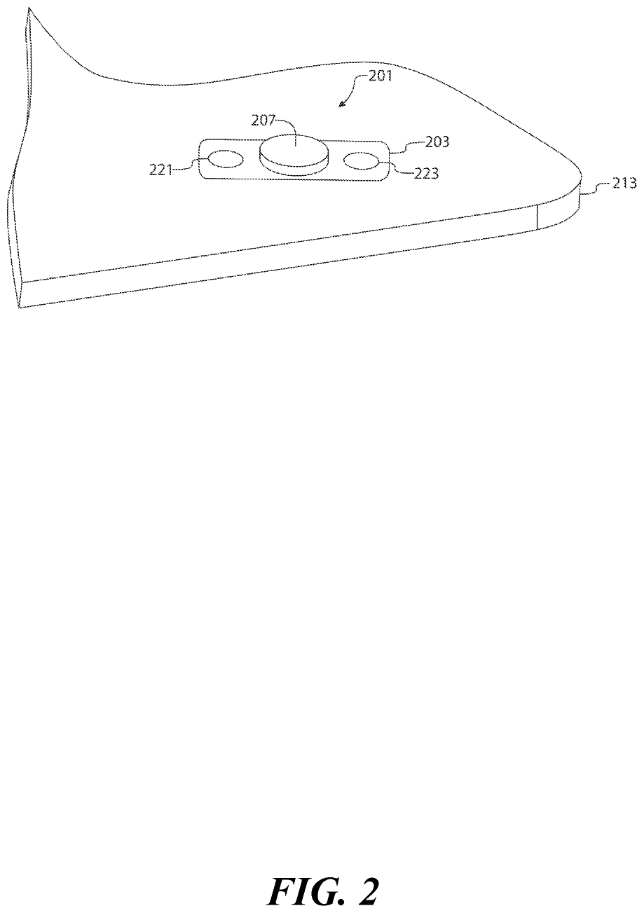

The end effector of Embertson et al. is equipped with a wafer pad 800 (see FIGS. 1-2) which is preferably made of polyether ether ketone (PEEK). Each wafer pad 800 preferably includes a support surface 801 and a gripping surface 802. The gripping surfaces 802 of the front and back wafer pads of the first blade 150 and the front and back wafer pads of the second blade 150b are adapted to automatically center (align) the wafer 50 over the first and second blades 150a, 150b of the end effector 100 when the wafer 50 is held by the end effector 100. The support surface 801 is a ramped surface and the gripping surface 802 is a vertical or inclined surface, and the ramped support surface 801 is ramped upwardly toward the gripping surface 802. However, similar to the design of the pads in the end effector of Bonora et al., the wafer support pads in this end effector engage the entire portion of the edge of the wafer which extends over the pad, and thus contribute unnecessarily to particle generation. Moreover, the wafer support pads in the device of Embertson et al. are at best secured to the end effector only on one side, which can result in changes to the profile of the opposing side (for example, as a result of torsion).

It has now been found that the foregoing infirmities may be addressed with the devices and methodologies disclosed herein. In preferred embodiments of these devices and methodologies, an end effector is provided with wafer support pads disposed in a complimentary shaped depression on the surface of the end effector. Each wafer support pad is equipped with a rounded protrusion. This rounded protrusion provides a reduced contact surface compared, for example, to the wafer support pads of Bonora et al. and Embertson et al. Moreover, opposing sides of the wafer support pad are equipped with apertures through which a suitable fastener may extend, thus rigidly (yet releasably) securing the wafer support pad to the end effector. In addition, the apertures, associated fasteners and complimentary shaped depression provide a means by which the wafer support pad may be registered to the surface of the end effector and rigidly held in place thereon. This arrangement allows the wafer pads to be readily replaced without replacement of the end effector itself, and provides a reproduceable wafer pad height that avoids the need for recalibration of the associated tool after wafer pad replacement.

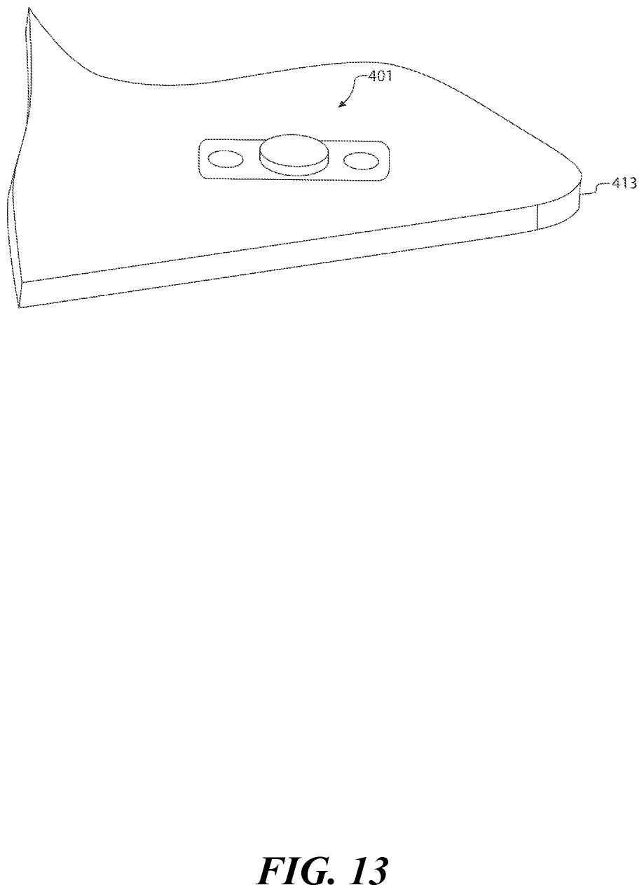

The devices and methodologies disclosed herein may be further understood with respect to the particular, non-limiting embodiments depicted in FIGS. 1-18. However, one skilled in the art will appreciate that various modifications may be made to these embodiments without departing from the scope of the present disclosure.

FIGS. 1-3 depict a first particular, non-limiting embodiment of an end effector in accordance with the teachings herein. With reference to FIG. 1, a wafer pad 201 is provided which includes a base plate 203 having a central protrusion 205 thereon. In this particular embodiment, the base plate 203 and the central protrusion 205 are an integral construct. The central protrusion 205 is equipped with a rounded contact surface 207 upon which a wafer will rest during use. First 209 and second 211 apertures are disposed on first and second sides of the base plate 203.

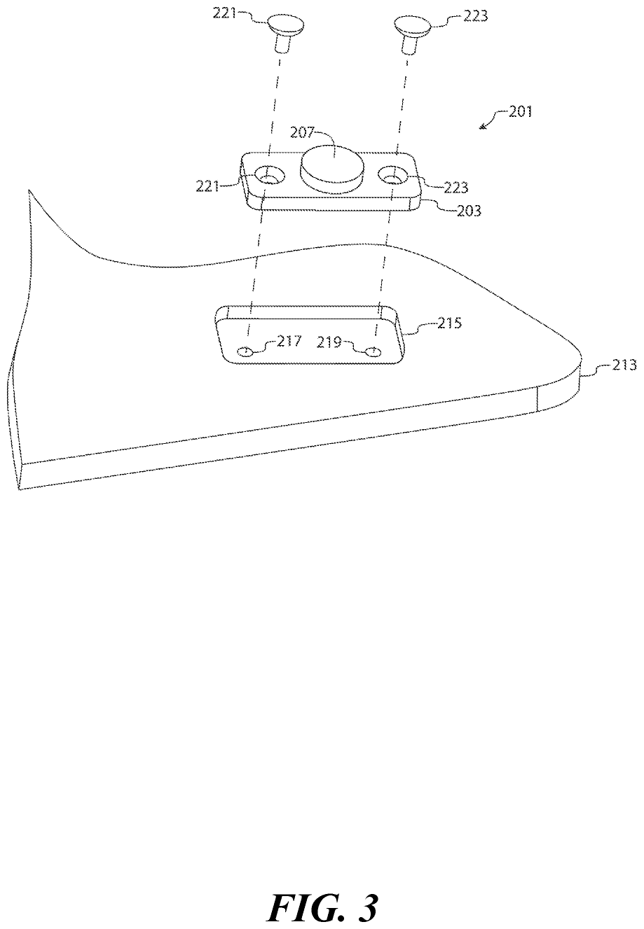

FIGS. 2-3 depict the manner in which the wafer pad 201 is secured to an end effector blade 213. As seen in FIG. 3, the end effector blade 213 is equipped with depressions 215 that are complimentary in shape to the base plate 203. Each depression 215 is equipped with first 217 and second 219 apertures that engage first 221 and second 223 fasteners to secure the wafer pad 201 in place. For example, in some embodiments, the first 217 and second 219 apertures may be threaded apertures, and the first 221 and second 223 fasteners may be equipped with complimentary shaped threaded shafts that rotatingly engage the first 217 and second 219 apertures.

As seen in FIG. 2, after being secured in place, the first 221 and second 223 fasteners and the base plate 203 are flush with the planar surface of the end effector blade 213. Consequently, during use, only the contact surface 207 of the central protrusion 205 comes into contact with a wafer.

It will be appreciated from the foregoing that the manner in which the wafer pads 201 are secured to the end effector blade 213 provides a convenient means to quickly replace the wafer pads 201 without replacing the end effector blade 213 itself. Moreover, the depressions 215 (see FIG. 3), the first 217 and second 219 apertures and the first 221 and second 223 fasteners provide a means for registering the wafer pads 201 to the surface of the end effector blade 213, thus avoiding the need to recalibrate the associated tool after wafer pad replacement.

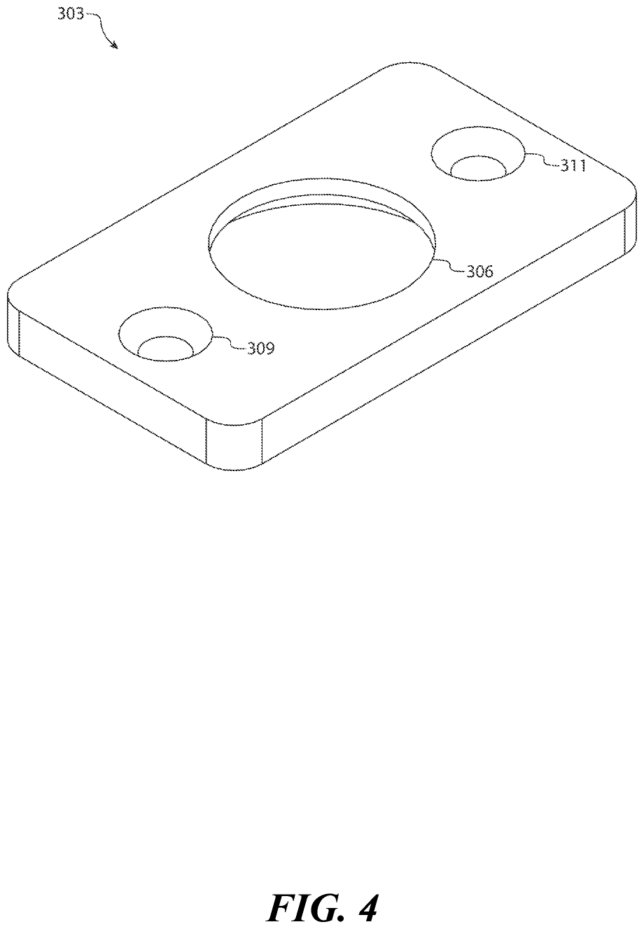

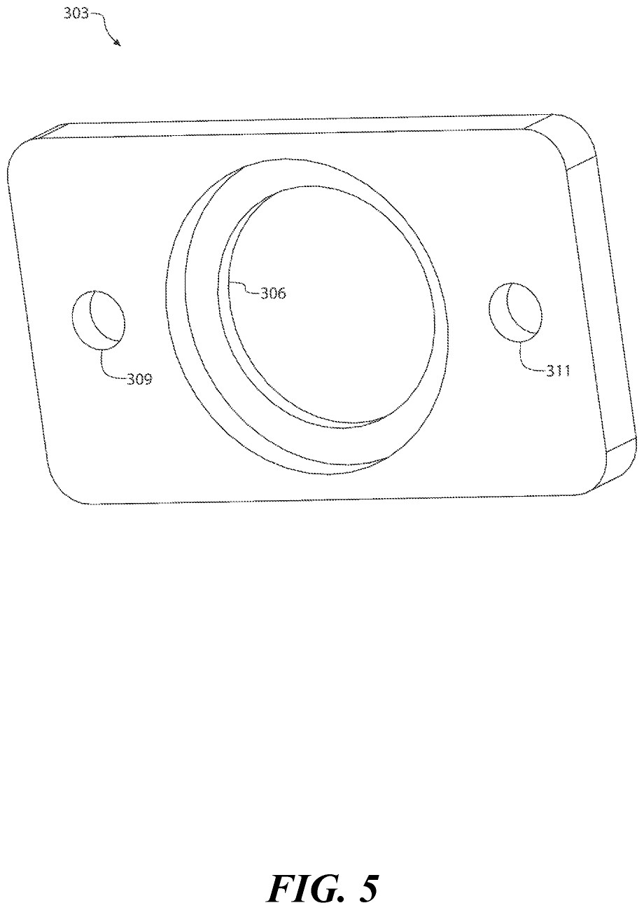

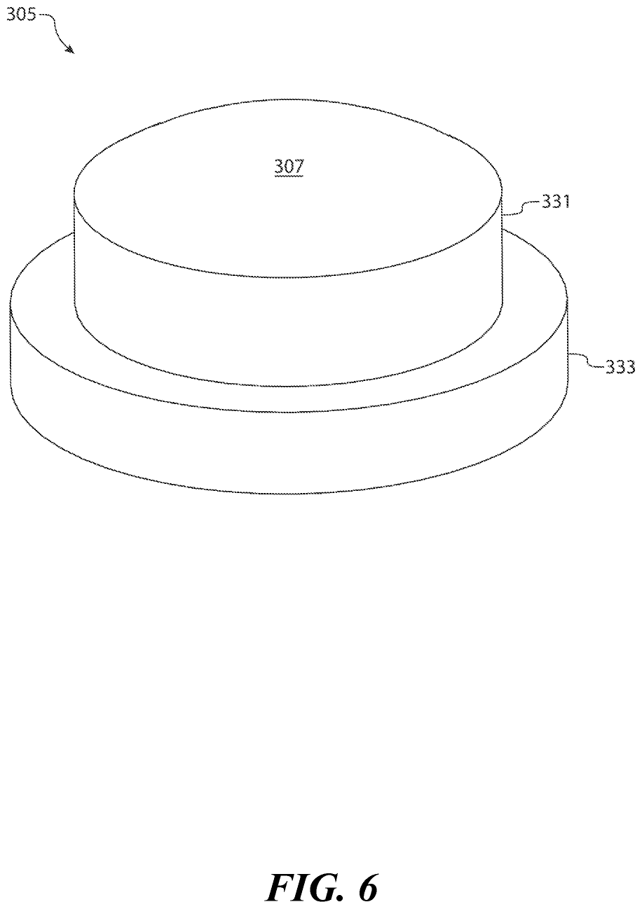

FIGS. 4-9 depict a second particular, non-limiting embodiment of a wafer pad 301 (see FIG. 8) in accordance with the teachings herein. The wafer pad 301 in this embodiment includes a base plate 303 (see FIGS. 4-5) having a central aperture 306 therein through which a central protrusion 305 extends (see FIG. 9). In this particular embodiment (and in contrast to the embodiment of FIGS. 1-3), the base plate 303 and the central protrusion 305 are discrete components. The central protrusion 305 is equipped with a rounded surface 307 (see FIG. 6) upon which a wafer will rest during use. As seen in FIGS. 4-5, first and second apertures 309, 311 are disposed on first and second sides of the base plate 303 to accommodate first 321 and second 323 fasteners (see FIG. 9) which are used to secure the base plate 303 to an end effector blade 313.

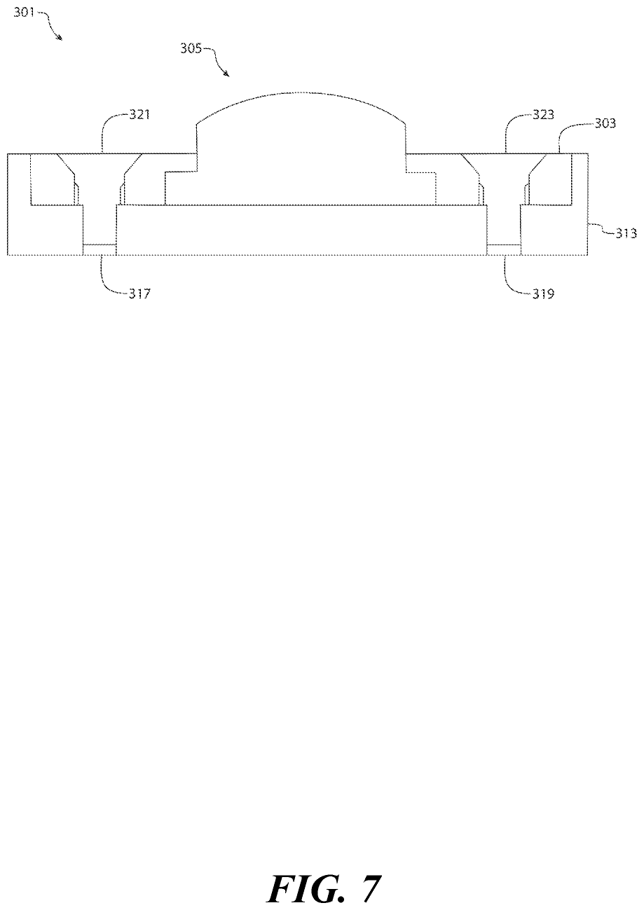

FIGS. 7 and 9 depict the manner in which the wafer pad 301 is secured to an end effector 313. As seen therein, the end effector 313 is equipped with depressions 315 that are complimentary in shape to the base plate 303. Each depression 315 is equipped with first 317 and second 319 apertures that engage first 321 and second 323 fasteners to secure the wafer pad 301 in place. For example, in some embodiments, the first 317 and second 319 apertures may be threaded apertures, and the first 321 and second 323 fasteners may be threaded fasteners that rotatingly engage the first 317 and second 319 apertures.

As previously noted, the wafer pad 301 in this embodiment is similar in many respects to the wafer pad 201 of FIGS. 1-3, but differs in that the base plate 303 and central protrusion 305 are discrete components. Moreover, in this embodiment, the base plate 303 is preferably metallic (and more preferably, aluminum) and the central protrusion 305 is preferably ceramic, while both the base plate 303 and the central protrusion 305 of the wafer pad 201 of FIGS. 1-3 are preferably ceramic.

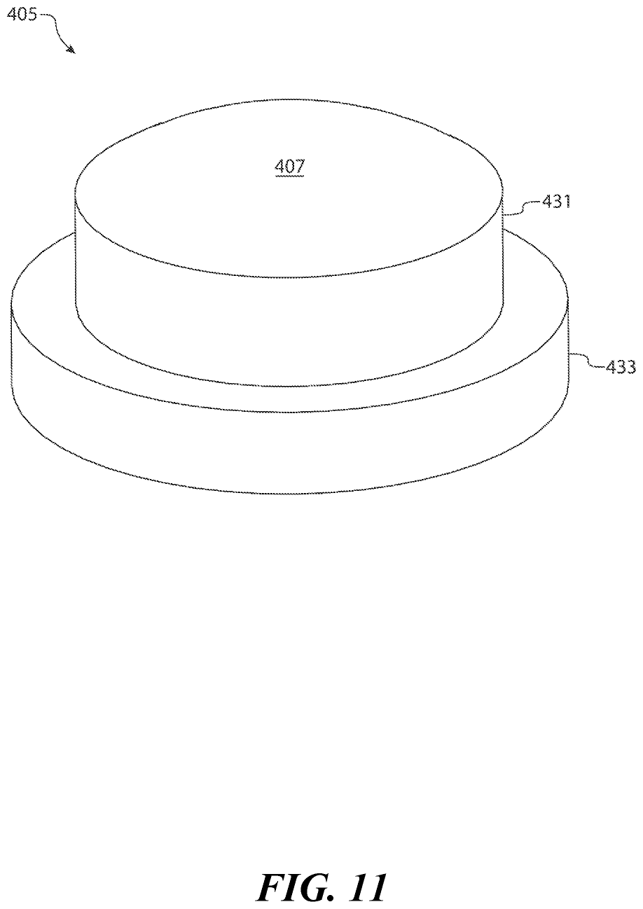

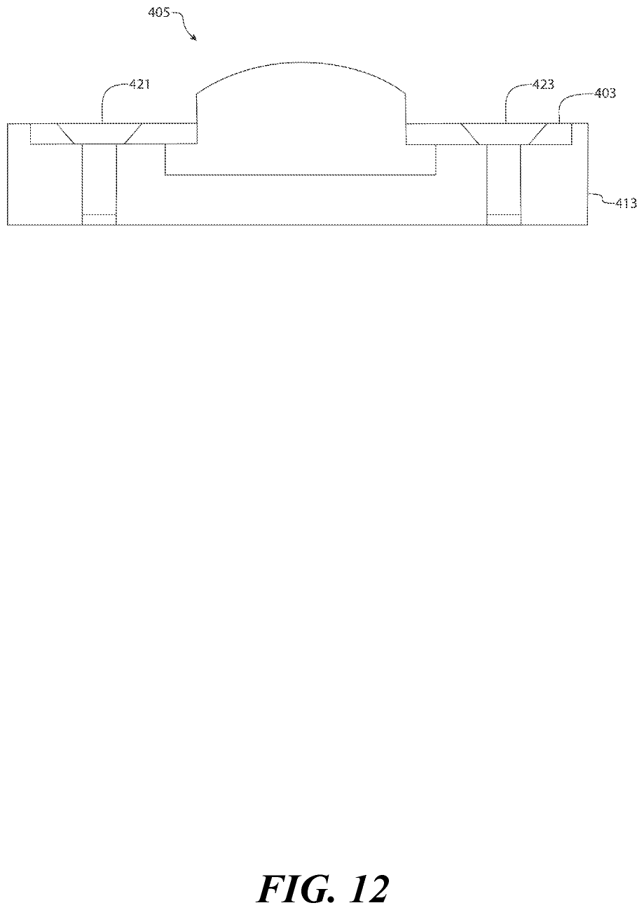

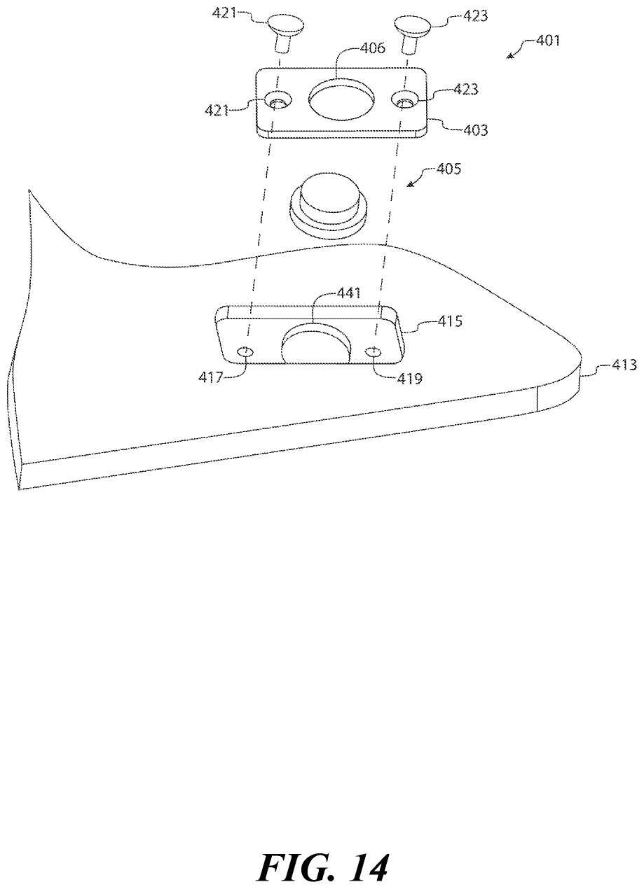

FIGS. 10-14 illustrate a third particular, non-limiting embodiment of a wafer pad 401 in accordance with the teachings herein. As seen in FIGS. 12 and 14, the wafer pad 401 in this embodiment includes a base plate 403 (shown in greater detail in FIG. 10) having a central aperture 406 therein through which a central protrusion 405 (shown in greater detail in FIG. 11) extends. In this particular embodiment (as in the embodiment of FIGS. 4-8), the base plate 403 and the central protrusion 405 are discrete components. The central protrusion 405 is equipped with a rounded surface 407 (see FIG. 11) upon which a wafer will rest during use. First and second apertures 409, 411 are disposed on first and second sides of the base plate 403.

FIGS. 12 and 14 depict the manner in which the wafer pad 401 is secured to an end effector 413. As seen therein, the end effector 413 is equipped with depressions 415 (see FIG. 14) that are complimentary in shape to the base plate 403. Each depression 415 is equipped with first 417 and second 419 apertures that engage first 421 and second 423 fasteners to secure the base plate 403 (and hence the wafer pad 401) in place. For example, in some embodiments, the first 417 and second 419 apertures may be threaded apertures, and the first 421 and second 423 fasteners may be threaded fasteners that rotatingly engage the first 417 and second 419 apertures.

The wafer pad 401 in this embodiment is similar in many respects to the wafer pad 301 of FIGS. 4-9, but differs in that the base plate 403 does not incorporate a counterbore into the bottom surface thereof. This may be appreciated by comparing the cross-sectional views of FIGS. 7 and 12.

The effect of the counterbore may be appreciated with respect to the central protrusion 405 depicted in FIG. 11 (which is identical to the central protrusion 305 depicted in FIG. 6). As seen therein, the central protrusion 405 includes first 433 and second 431 conical portions. The second conical portion 431 terminates in a rounded protrusion that forms the wafer contact surface 407. Since the baseplate 403 does not include a counterbore, the depression 415 in the end effector blade 413 is equipped with a central recess 441 (see FIG. 14) to accommodate the first conical portion 433 of the central protrusion 405. By contrast, in the embodiment depicted in corresponding FIG. 9, the depression 315 in the end effector blade 313 does not require a central depression. These considerations may make one of the foregoing designs preferably over the other one in certain applications.

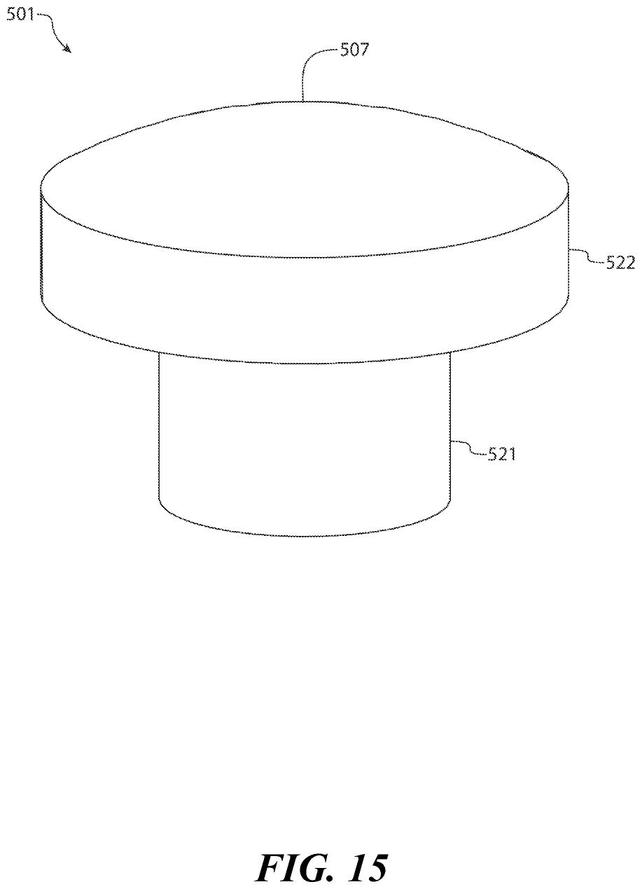

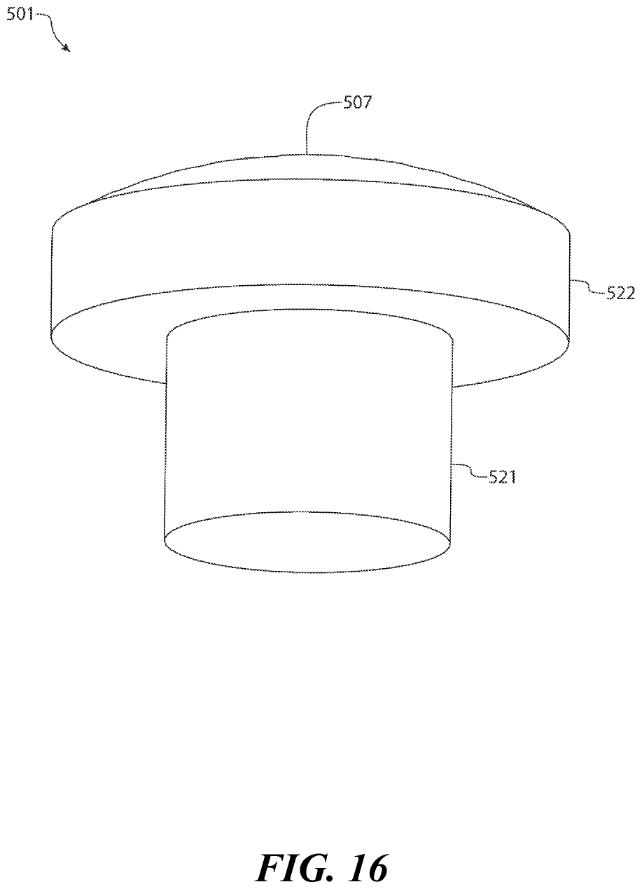

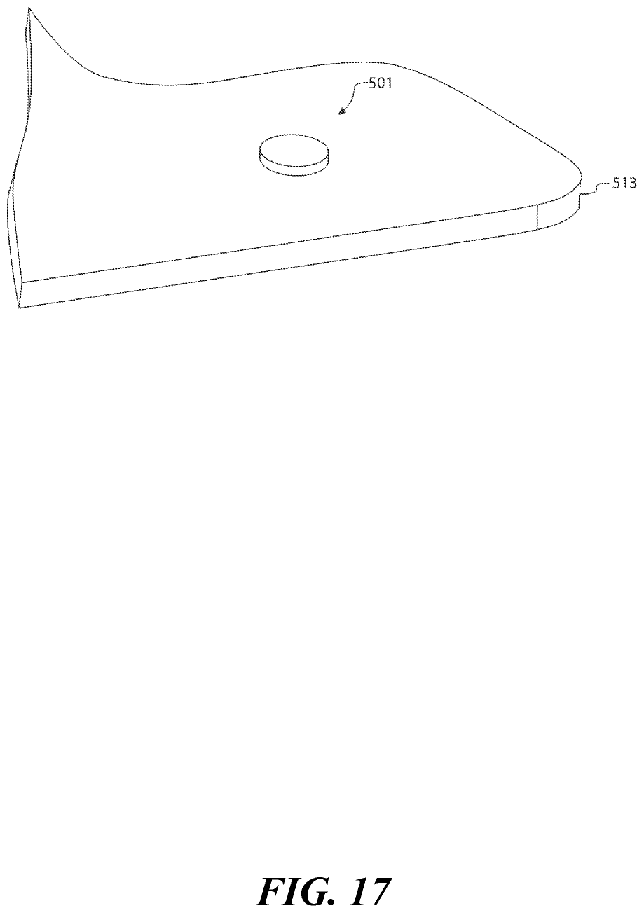

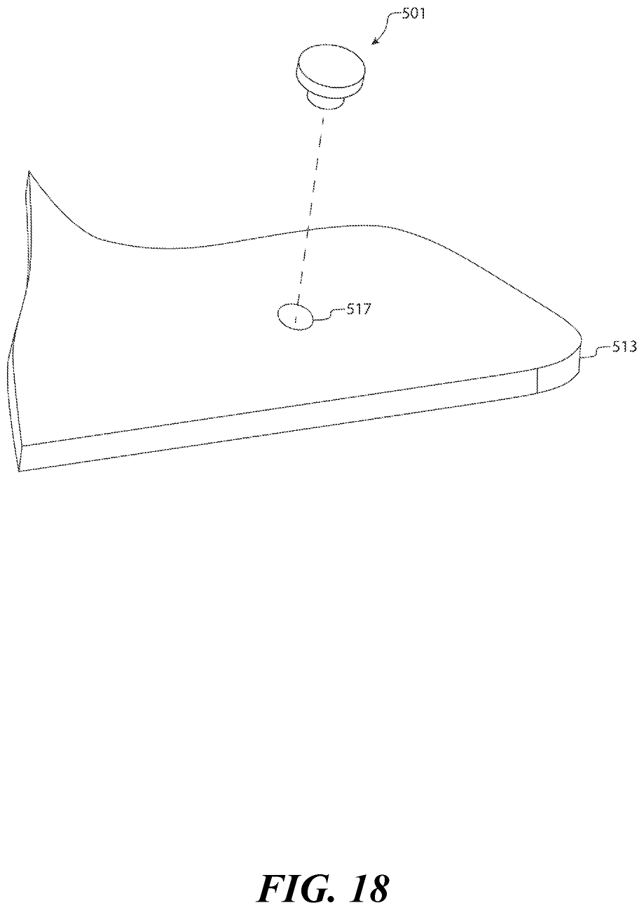

FIGS. 15-18 illustrate a fourth particular, non-limiting embodiment of a wafer pad 501 in accordance with the teachings herein. As seen in FIGS. 15-16, the wafer pad 501 in this embodiment is essentially a mushroom-shaped protrusion which preferably comprises one or more ceramic materials. The wafer pad 501 is equipped with a shaft 521 which engages an aperture 517 (see FIG. 18) in the end effector blade 513, and a head 522 with a rounded surface 507 upon which a wafer will rest during use. In a preferred embodiment, the aperture 517 and shaft 521 are complimentary in shape and are threaded. Hence, as shown in FIGS. 17-18, the shaft 521 rotatingly engages the aperture 517, thus allowing the wafer pad 501 to be readily installed on, or removed from, the end effector blade 513.

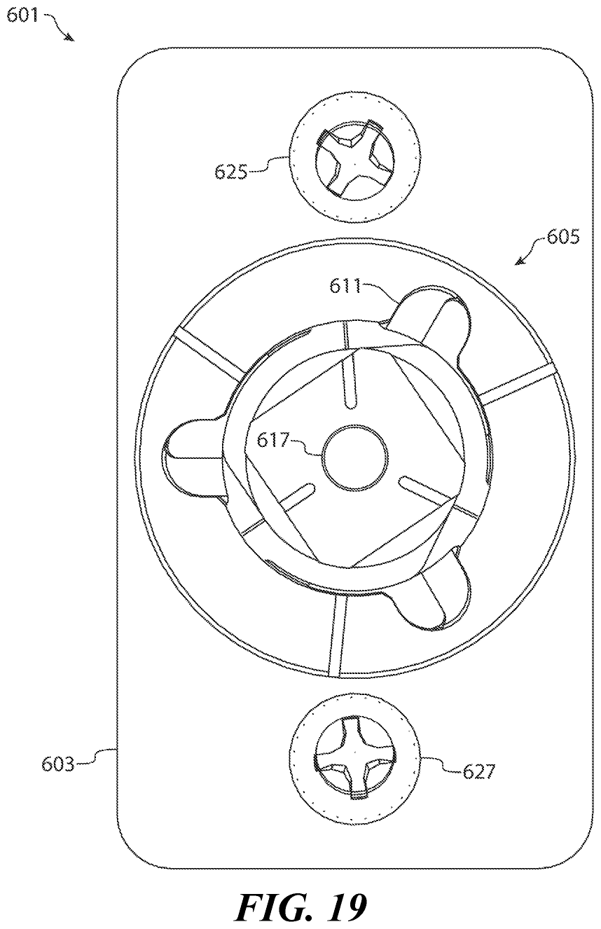

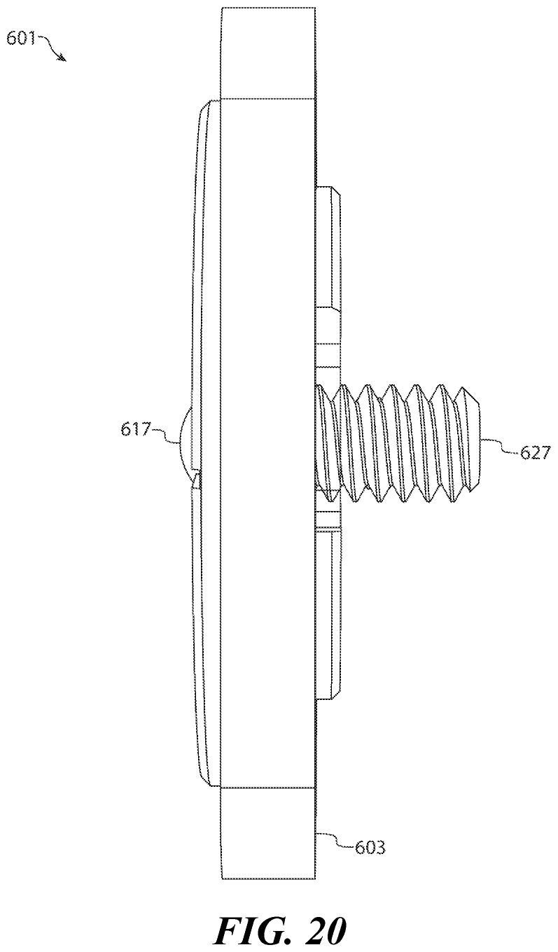

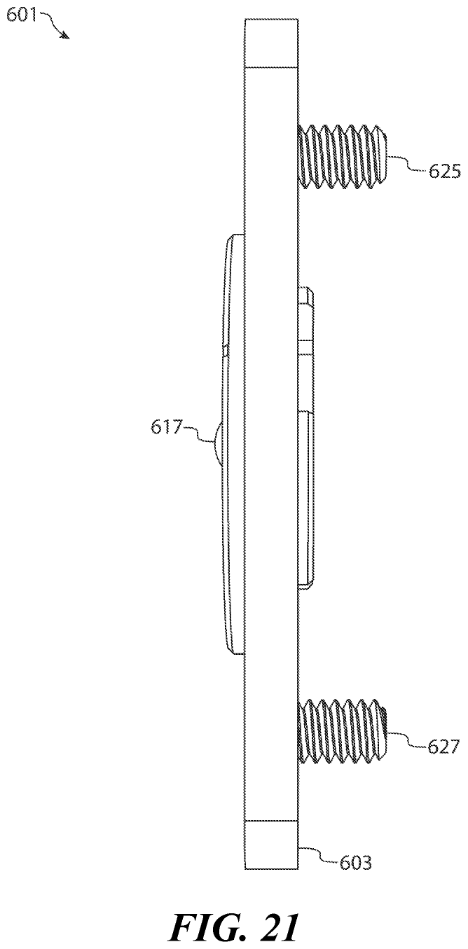

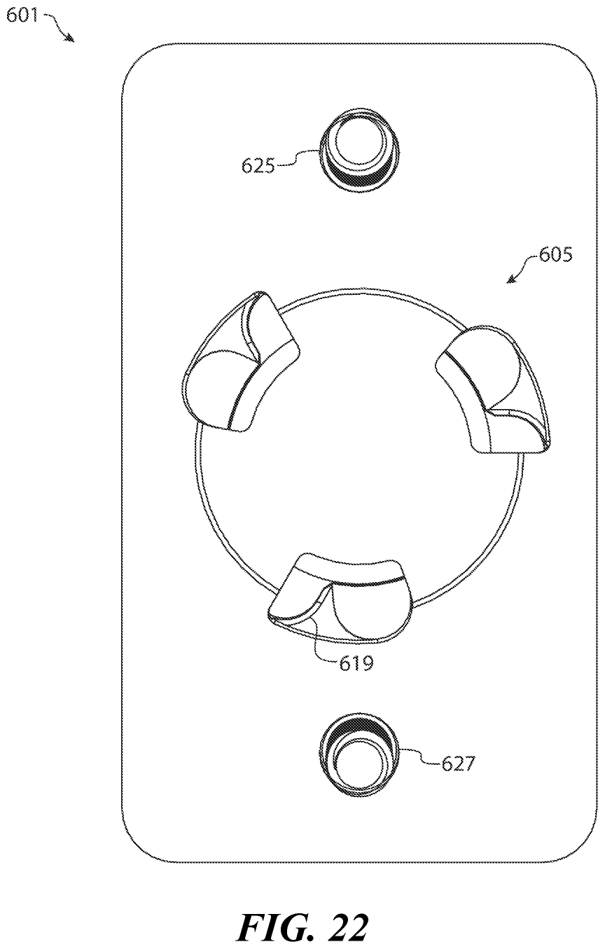

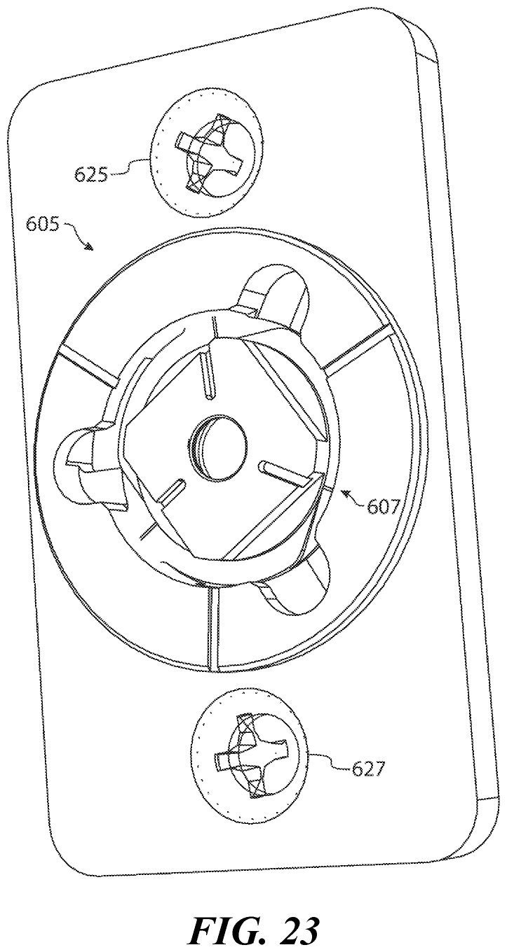

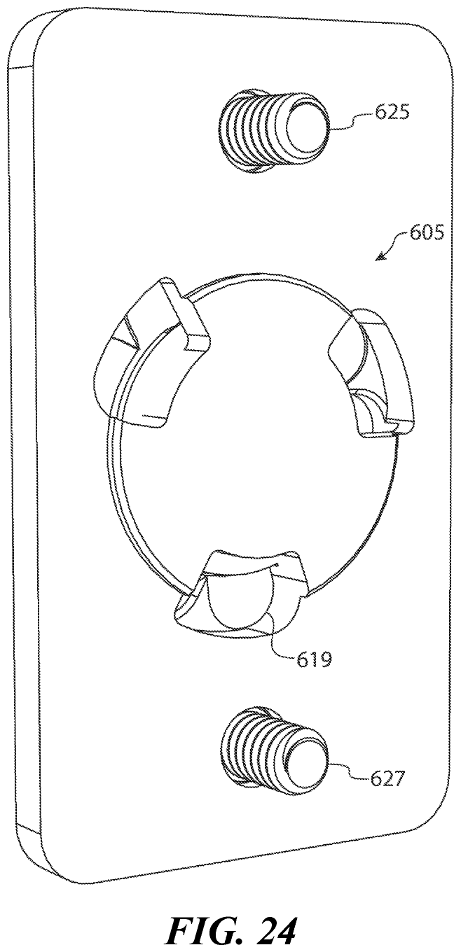

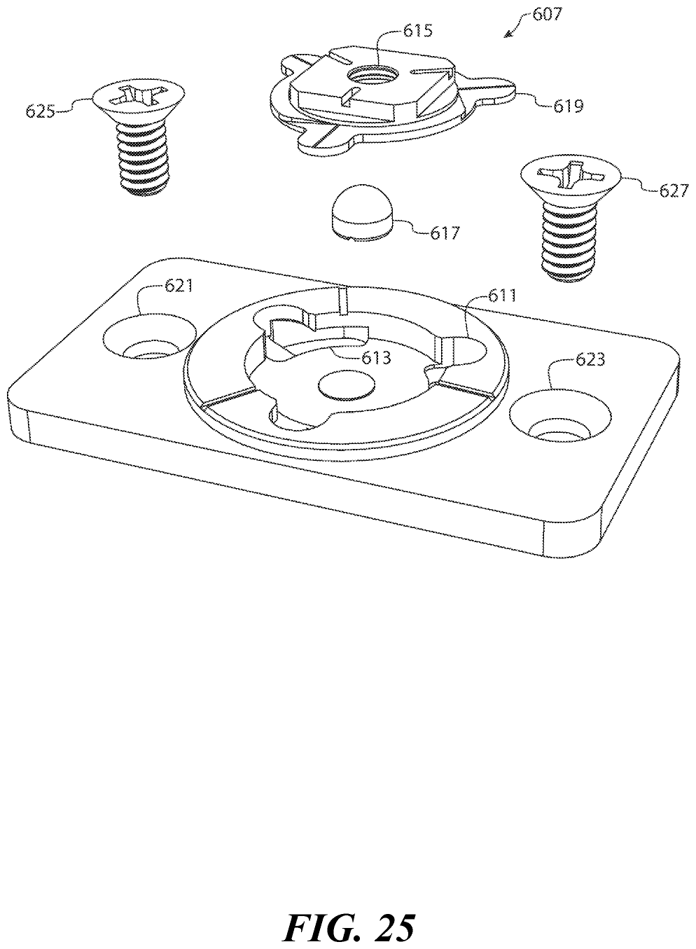

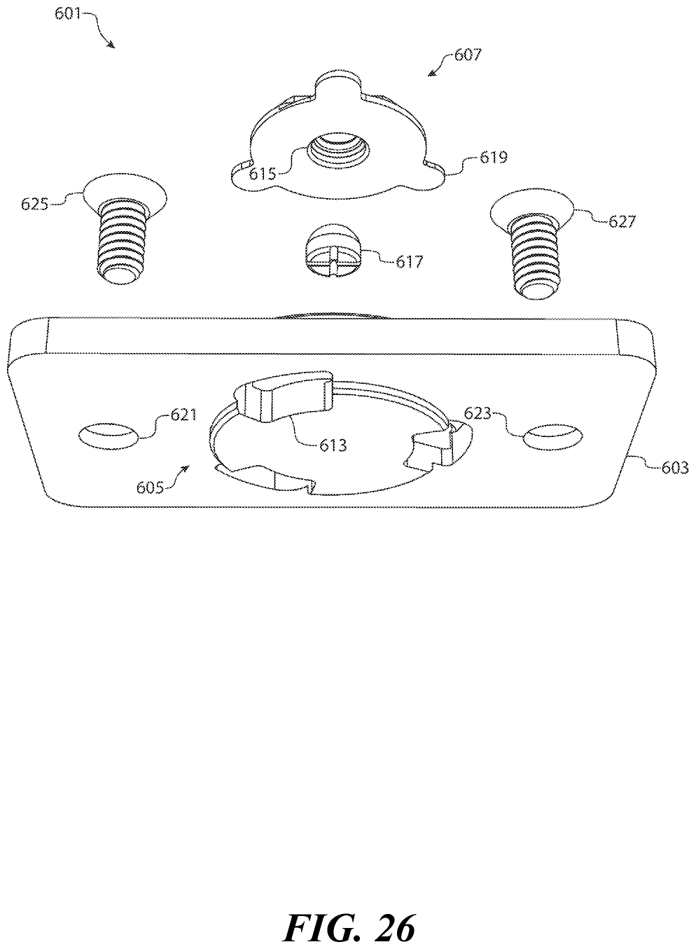

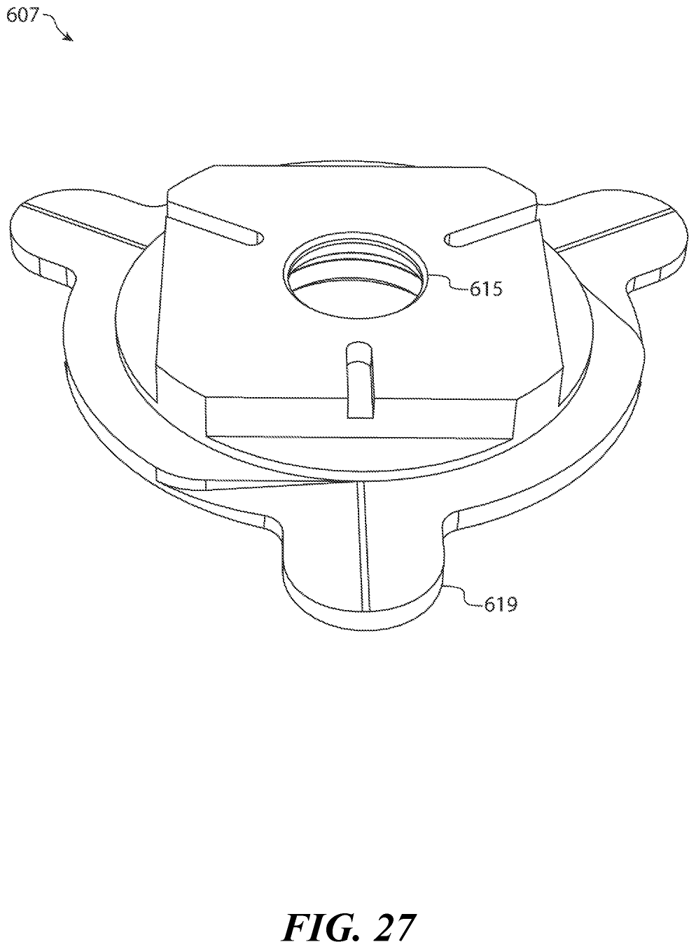

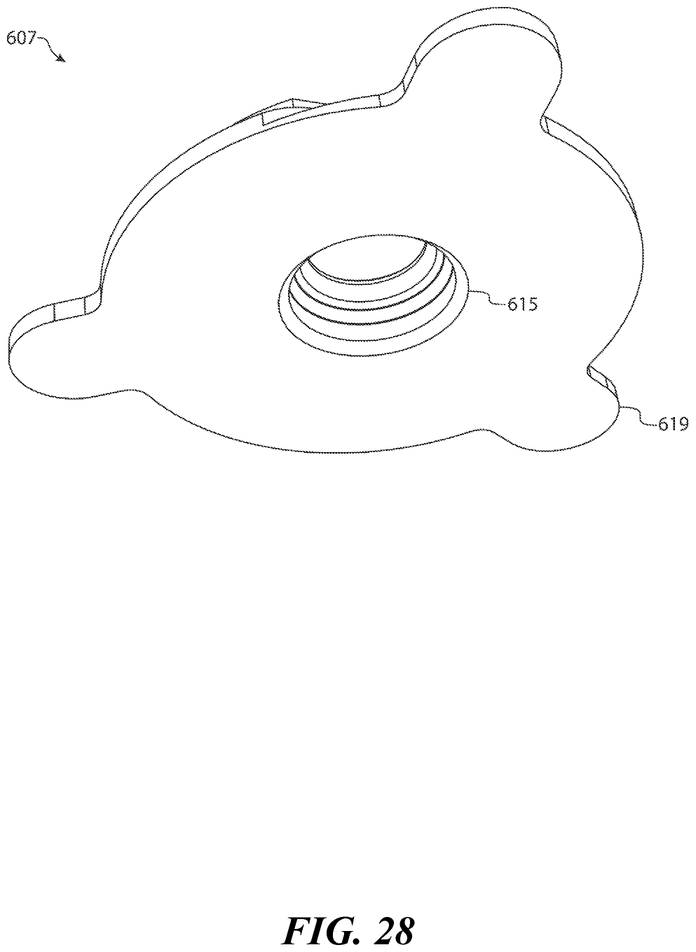

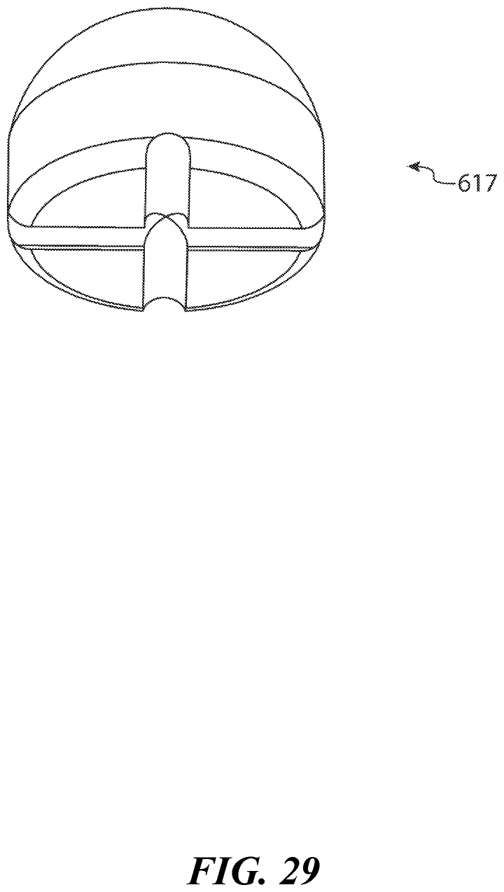

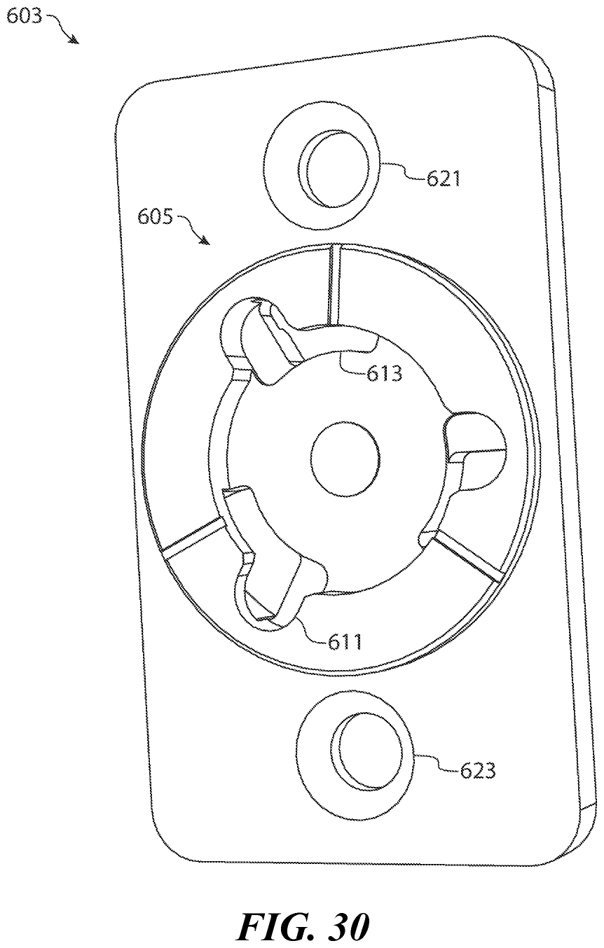

FIGS. 19-30 illustrate a fifth particular, non-limiting embodiment of a wafer pad 601 in accordance with the teachings herein. As best seen in FIGS. 25-26, the wafer pad 601 in this embodiment includes a base plate 603 (shown in greater detail in FIG. 30) equipped with a protrusion mount receptacle 605 that releasably engages a protrusion mount 607 (shown in greater detail in FIGS. 27-28). The protrusion mount receptacle 605 has a central aperture 609 therein which is equipped with a plurality of vertical indentations 611 on the periphery thereof. Each of the vertical indentations 611 opens to a horizontal slot 613 positioned peripherally at the base of the central aperture 609. The protrusion mount 607 is equipped with a central eye 615 through which a protrusion 617 extends. The protrusion mount 607 is further equipped with a plurality of laterally extending fingers 619.

In use, the protrusion 617 is seated in the central eye 615 of the protrusion mount 607. The protrusion mount 607 is then positioned over the protrusion mount receptacle 605 such that the laterally extending fingers 619 of the protrusion mount 607 are aligned with the vertical indentations 611 of the protrusion mount receptacle 605. The protrusion mount 607 is then inserted into the protrusion mount receptacle 605 until it pressingly engages the bottom of the central aperture 609. The protrusion mount 607 is then rotated clockwise such that the laterally extending fingers 619 of the protrusion mount 607 engage the horizontal slots 613, thus securing the protrusion mount 607 into place.

The base plate 603 is further equipped with first 621 and second 623 apertures through which first 625 and second 627 fasteners extend. The first 621 and second 621 fasteners rotatingly engage complimentary shaped threaded apertures (not shown) provided on a wafer blade. Though not illustrated, the base plate 603 is adapted to fit into a complimentary shaped recess in the wafer blade in a manner similar to that depicted in the embodiment of the wafer pad 301 shown in FIG. 9.

It will be appreciated from the foregoing that the present embodiment allows for the fast, easy and tool-free removal and replacement of the protrusion 605 without the need to replace or recalibrate the associated end effector. Indeed, it is not even necessary for this purpose to replace the associated base plate 603. This allows for minimal downtime of the associated semiconductor processing equipment and frequent replacement of the protrusions 617.

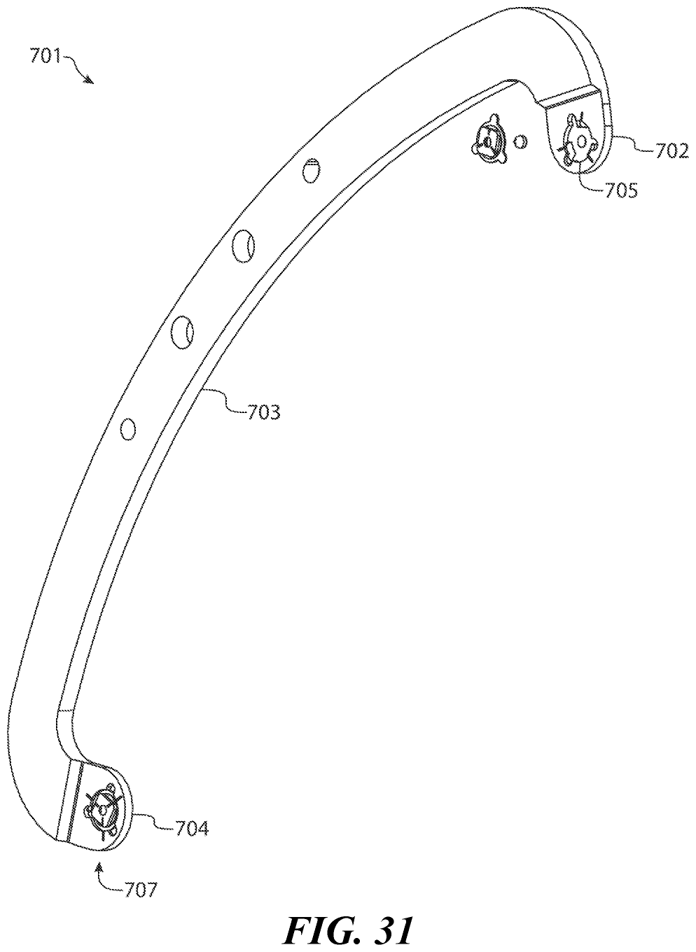

FIG. 31 illustrates a particular, non-limiting embodiment of a fin assembly 701 in accordance with the teachings herein which is equipped with machined in receptacles 705 for protrusion mounts 707. The fin assembly 701 in this embodiment includes a curved, elongated body 703 having first 702 and second 704 terminal portions. The first 702 and second 704 terminal portions are equipped with protrusion mounts 707 of the general type depicted in FIGS. 19-30.

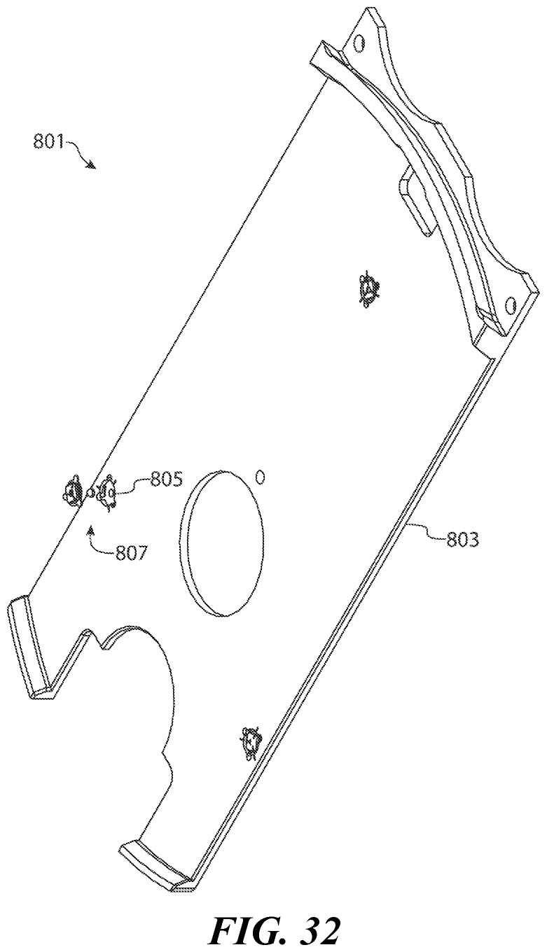

FIG. 32 illustrate a sixth particular, non-limiting embodiment of an end effector 801 in accordance with the teachings herein which is equipped with machined in receptacles 805 for protrusion mounts 807. The end effector 801 in this embodiment includes a flattened body 803. The flattened body 803 is equipped with protrusion mounts 807 of the general type depicted in FIGS. 19-30.

The above description of the present invention is illustrative, and is not intended to be limiting. It will thus be appreciated that various additions, substitutions and modifications may be made to the above described embodiments without departing from the scope of the present invention. Accordingly, the scope of the present invention should be construed in reference to the appended claims. It will also be appreciated that the various features set forth in the claims may be presented in various combinations and sub-combinations in future claims without departing from the scope of the invention. In particular, the present disclosure expressly contemplates any such combination or sub-combination that is not known to the prior art, as if such combinations or sub-combinations were expressly written out.

1. A robotic end effector, comprising:
an end effector blade; and
a plurality of wafer support pads disposed on the surface of said blade;
wherein each of said plurality of wafer support pads includes a pad body having a central protrusion and having first and second fasteners disposed on opposing sides of said central protrusion.

2. The robotic end effector of claim 1, wherein each of said wafer support pads is disposed in a in complimentary shaped depression on the surface of said blade.

3. The robotic end effector of claim 1, wherein said first fastener extends through a first aperture in said pad body, and wherein said second fastener extends through a second aperture in said pad body.

4. The robotic end effector of claim 1, wherein said pad body and said central protrusion form an integral construct.

5. The robotic end effector of claim 1, wherein said pad body and said central protrusion are discrete components, wherein said pad body is equipped with a central aperture, and wherein said central protrusion extends through said central aperture.

6. The robotic end effector of claim 5, wherein said central protrusion comprises first and second portions, wherein said first portion has a first annular peripheral surface.

7. The robotic end effector of claim 6, wherein said second portion has a second annular peripheral surface that is concentric with said first annular peripheral surface.

8. The robotic end effector of claim 7, wherein said second portion is equipped with a convex wafer contact surface.

9. The robotic end effector of claim 8, wherein said wafer contact surface is rounded.

10. The robotic end effector of claim 7, wherein said first annular peripheral surface has a larger diameter than said second annular peripheral surface.

11. The robotic end effector of claim 1, further comprising an end effector blade having a planar surface, wherein said pad body has first and second major surfaces, and wherein said first major surface of said pad body is parallel to the planar surface of said end effector blade.

12. The robotic end effector of claim 1, further comprising an end effector blade having a planar surface, wherein said pad body has first and second major surfaces, and wherein said first major surface of said pad body is coplanar with the planar surface of said end effector blade.

13. The robotic end effector of claim 11, wherein said second major surface of said pad body is counterbored.

14. The robotic end effector of claim 11, wherein said first and second major surfaces of said pad body are parallel.

15. The robotic end effector of claim 14, wherein said second major surface of said pad body is planar.

16. A robotic end effector, comprising:
an end effector blade having a plurality of apertures therein; and
a plurality of wafer support pads disposed on the surface of said blade;
wherein each of said plurality of wafer support pads includes a rounded head disposed on a shaft, and wherein said shaft rotatingly engages one of said plurality of apertures.

17. The robotic end effector of claim 16, wherein said shaft is cylindrical in shape.

18. The robotic end effector of claim 16, wherein said head is convex.

19. The robotic end effector of claim 16, wherein said head includes a cylindrical portion which terminates in a convex portion.

20. A robotic end effector, comprising:
an end effector blade; and
a plurality of wafer support pads disposed on said end effector blade;
wherein each of said plurality of wafer support pads includes (a) a base plate, (b) a protrusion mount receptacle disposed on said base plate, (c) a protrusion mount which releasably engages said protrusion mount receptacle, and (d) a protrusion mounted on said protrusion mount such that said protrusion extends above the first surface of said blade.

21. The robotic end effector of claim 20, wherein each of said plurality of wafer support pads is disposed within a recess on said end effector blade.

22. The robotic end effector of claim 20, wherein each recess is complimentary in shape to the wafer support pad disposed within it.

23. The robotic end effector of claim 20, wherein said protrusion mount releasably engages said protrusion.

24. The robotic end effector of claim 20, wherein said protrusion mount is equipped with a plurality of laterally extending fingers.

25. The robotic end effector of claim 24, wherein said protrusion mount receptacle has a central aperture which is equipped with a plurality of peripherally disposed slots, and wherein said laterally extending fingers rotatingly engage said peripherally disposed slots.

26. The robotic end effector of claim 25, wherein each of said peripherally disposed slots has an opening therein.

27. The robotic end effector of claim 20, wherein said base plate is equipped with first and second apertures having first and second threaded fasteners which extend therethrough.
